(19) United States
(12) Patent Application Publication
(10) Pub. No.: US 2006/0249203 A1
(43) Pub. Date: Nov. 9, 2006

(54) Solar power module having carbon nanotubes

(75) Inventors: Jung-Yu Li, Hsinchu (TW); Shih-Pu Chen, Hsinchu (TW); Yi-Ping Lin, Hsinchu (TW); Wen-Liang Huang, Hsinchu (TW); Ching-Sung Hsiao, Hsinchu (TW)

Correspondence Address: BIRCH STEWART KOLASCH & BIRCH, PO BOX 747, FALLS CHURCH, VA, 22040-0747, US

(73) Assignee: Industrial Technology Research Institute

(21) Appl. No.: 11/344,089

(22) Filed: Feb. 1, 2006

(30) Foreign Application Priority Data
Feb. 2, 2005 (TW) 94103247

(51) Int. Cl. H01L 31/00

(52) U.S. Cl. 136/263

(57) ABSTRACT

A solar power module having carbon nanotubes comprises an at-least partial transparent first conducting layer, a second conducting layer for outputting electrons, and a mixing layer for donating and further forwarding electrons and holes excited by the light penetrating through the first conducting layer, in which the mixing layer is sandwiched between the first conducting layer and the second conducting layer. The mixing layer further includes a plurality of carbon nanotubes grown from either the first conducting layer or the second conducting layer for forwarding electrons respectively to either the first conducting layer or the second conducting layer.

### BACKGROUND OF THE INVENTION

(1) Field of the Invention

The invention relates to a solar power module, and more particularly to a module that utilizes carbon nanotubes.

(2) Description of the Prior Art

In past decades, various researches have made the solar power one of feasible and economic future power sources, and currently research efforts have been devoted to enhancing the solar power efficiency (optic-electric conversion efficiency). In the market, the solar power has been widely applied to low-power consumer electronic products such as electronic watches, calculators, and so on. Also, the trend of the application of the solar power is recently aiming at the high-power products such as the building facilities, communication vehicles and so on.

Besides the concern of the solar power efficiency, the production cost is also another concern in applying the solar powered products. In this point of view, a new low-cost solar cell laminated by a polymer electron donor layer and a carbon electron acceptor layer is introduced to replace the traditional high-cost single crystal solar cell. Referring to FIG. 1, a solar cell disclosed by U.S. Pat. No. 5,986,206 is shown. The solar cell includes an electron donor layer 1 made of a conducting polymer and an electron acceptor layer 3 made of nanoscale carbon particles. By providing the conducting polymer and the nanoscale carbon particles, the solar cell can then have a higher optic-electric conversion efficiency mainly contributed by providing a broader work area, a low production cost, and a property of flexibility. Further, for the solar cell is flexible, the electron donor layer and the electron acceptor layer can be patterned so as to increase their work areas and thus to achieve a higher optic-electric conversion efficiency.

It is easy to locate that two main factors to dominate the application of the solar cells are the optic-electric conversion efficiency and the production cost. Therefore, how to increase the optic-electric conversion efficiency of the solar cells and how to reduce the production cost are two topics urgent to be resolved in the art.

### SUMMARY OF THE INVENTION

Accordingly, it is an object of the present invention to provide a solar power module having carbon nanotubes, which the carbon nanotube is used as the electron acceptor and a conducting organic material is used as the electron donor that wraps the carbon nanotube. For the carbon nanotube has versatile nonplanar characteristics in multi-directional growth and a hollow pipe shape, the introduction of the carbon nanotube as the electron acceptor can greatly increase its contact area with the conducting organic material and thus can improve the work performance of the electron acceptor. In addition, for the longitudinal length of the carbon nanotube is long enough to reduce the possibility of recombining the electron and the hole, the optic-electric conversion efficiency of the solar power module can be increased.

On the other hand, for the major material of the carbon nanotube is the low-cost carbon, the production cost of the solar power module in accordance with the present invention can be greatly reduced.

In addition, for a major material to form the electron acceptor in the solar power module of the present invention is the carbon nanotube that extends arbitrarily in the electron donor layer, the contact area between the carbon nanotube and the conducting polymer can be substantially increased and so is the optic-electric conversion efficiency.

Furthermore, in the case that the solar power modules of the present invention are mounted on a flexible plate so as to make the combined product flexible, the contact area between the carbon nanotube and the conducting polymer as well as the optic-electric conversion efficiency can be further increased.

Therefore, to achieve the foregoing objects, the soloar power module having carbon nanotubes in accordance with the present invention can comprise a first conducting layer, a second conducting layer, a mixing layer sandwiched between the first layer and the second layer, and a plurality of carbon nanotubes connecting to the first conducting layer or the second conducting layer for transmitting the electrons to the first conducting layer or the second conducting layer. The first layer for accepting and emitting electrons or holes is at least partially light-permeable.

The second conducting layer is used to receive and further emit the electrons or the holes.

The mixing layer located between the first conducting layer and the second conducting layer can include a permeable conducting polymer and is used to provide the excitorn(electron-hole pair) after reacting with the light penetrating through the first conducting layer. The palymer can be adjusted the long chain structure(energy band gap) for matching solar spectrum.

In the present invention, the catalyst to grow the carbon nanotubes and to determine their positions can be formed on the first conducting layer or the second conducting layer. The catalyst can be Fe, Co, Ni, Pt, Pd, or Ag. The carbon nanotube of the present invention can be a single-walled carbon nanotube, a multi-walled carbon nanotube, or a nano carbon fiber structure and can be classified into an N-type nanotube.

In the present invention, the first conducting layer can be made of an indium oxide, a tin oxide, an indium tin oxide (ITO), or any metal oxide the like. Or, the first conducting layer can be an extreme thin metal foil such as a gold foil or a silver foil. PEDOT can be deposited between ITO and polymer for the enhancement of hole transportation.

In the present invention, the polymer can be a poly phenylethylene chemical such as a poly-3-hexylthiophene (P3HT), or a perylenetetracarboxylic-bis-benzimidazole (PTCBI).

By providing the solar power module having carbon nanotubes, advantages in the higher optic-electric conversion efficiency, lower production cost, and acceptable flexibility can be obtained.

### BRIEF DESCRIPTION OF THE DRAWINGS

The present invention will now be specified with reference to its preferred embodiment illustrated in the drawings, in which:

FIG. 1 is a schematic perspective view of a solar cell provided by U.S. Pat. No. 5,986,206;

FIG. 2 is a cross section view of a first embodiment of the solar power module having carbon nanotubes in accordance with the present invention; and

FIG. 3 is a cross section view of a second embodiment of the solar power module having carbon nanotubes in accordance with the present invention.

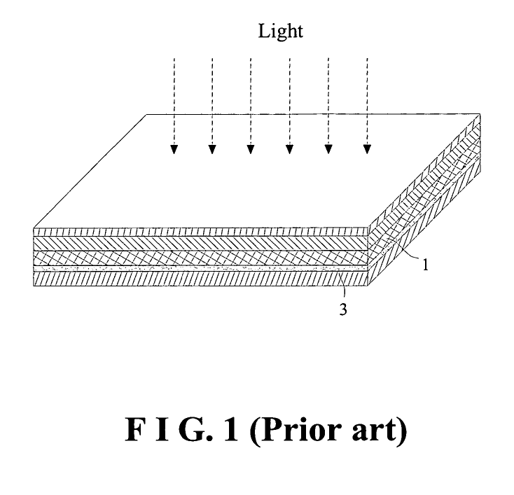

### DESCRIPTION OF THE PREFERRED EMBODIMENT

The invention disclosed herein is directed to a solar power module having carbon nanotubes. In the following description, numerous details are set forth in order to provide a thorough understanding of the present invention. It will be appreciated by one skilled in. the art that variations of these specific details are possible while still achieving the results of the present invention. In other instance, well-known components are not described in detail in order not to unnecessarily obscure the present invention.

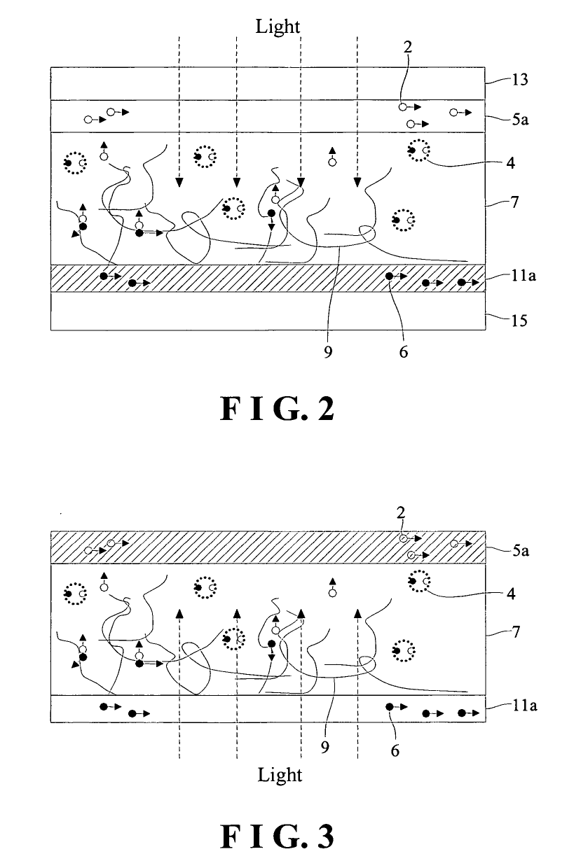

Referring now to FIG. 2, a cross section view of a first preferred embodiment of the solar power module having carbon nanotubes in accordance with the present invention is shown.

As shown, the solar power module comprises a first conducting layer Sa, an electron donor layer 7, a plurality of carbon nanotubes 9, and a second conducting layer 11a. Optionally, the first conducting layer 5a can be protected by an inert transparent layer 13 (a glass layer for example). The second conducting layer 11a can be layered on top of a substrate 15. Upon such an arrangement, the light can penetrate through the transparent first conducting layer 5a to the electron donor layer 7 for generating electrons or holes in this electron donor layer 7. The electrons produced in the electron donor layer 7 pass the carbon nanotubes 9 and then are output through the second conducting layer 11 a, while the holes are output through the first conducting layer 5a.

Preferably, the first conducting layer 5a is made of a transparent conducting material for allowing the light to penetrate. The transparent conducting material can be an indium oxide, a tin oxide, an indium tin oxide (ITO), or any metal oxide the like. Or, the first conducting layer 5a can be an extreme thin metal foil such as a gold foil or a silver foil. In some applications, the first conducting layer 5a can be partially transparent and can include an anti-reflection coating.

The electron donor layer 7 is sandwiched between the first conducting layer 5a and the second conducting layer 11a. The electron donor layer 7 is made of a electron-donor material which can react to the light for donating electrons or holes. The electron-donor material can be a P-type conjugate polymer which includes a π electron. The π electron can be excited to a conducting orbit (i.e. in an excited state) after receiving the light. Suitable materials of the P-type conjugate polymers for the electron donor layer 7 include the poly p-phenylene-vinylene (PPV) (preferably, the P3HT) and the perylenetetracarboxylic-bis-benzimidazole (PTCBI).

The carbon nanotubes 9 connected to the second conducting layer 11a as the electron acceptors are submerged in the electron donor layer 7 and are used to accept the electrons 6 generated in the electron donor layer 7 and to further forward these electrons 6 to the second conducting layer 11a. In the present invention, the outer surface and the inner surface of the carbon nanotube 9 play the heterojunction between the electron donor (the surrounding material 7) and the electron acceptor (the carbon nanotube 9). Such an pairing is similar to a p-n junction seen in the solar cell which has a silicon base chip and which utilizes a built-in electric field to separate the electrons and the holes. In the present invention, for both the outer and the inner surfaces of the carbon nanotube 9 can be used as the heterojunctions, the working area between the electron donors and the electron acceptors can be greatly increased. Further, for the carbon nanotube 9 extends weirdly in the electron donor layer 7 so as to provide a much wider heterojunction, the possibility of recombining the electron and the respective hole (4) has been substantially lowered. Thereby, the efficiency of the solar power module according to the present invention can be greatly increased.

Further, the carbon nanotube can be particularly doped to present an N-type carbon nanotube, and can be a single-walled carbon nanotube, a multi-walled carbon nanotube, or a nano carbon fiber structure.

On the other hand, for every of the carbon nanotubes 9 can extend arbitrarily or orderly in the electron donor layer 7, the effective contact area between the carbon nanotube and the surrounding conducting polymer 7 can be substantially increased and thus the optic-electric conversion efficiency can be greatly lifted as well.

In the present invention, the second conducting layer 11a for outputting the electrons 6 accepted from the electron donor layer 7 through the carbon nanotubes 9 can include the catalyst for growing the carbon nanotubes 9. The catalyst can be Fe, Co, Ni, Pt, Pd, or Ag. Also, the second conducting layer 11a can be used as the substrate to bear the electron donor layer.

In the present invention, the substrate 15 can be particularly provided to hold the second conducting layer 7. Preferably, the substrate 15 can be made of a ductile material (i.e. flexible), a metal or a silver.

By providing the solar power module of the present invention, the light can enter the electron donor layer 7, through the transparent first conducting layer 5a, to excite the electrons, the excited electrons are then forwarded to the second conducting layer 11 a through the carbon nanotubes 9.

Referring now to FIG. 3, a cross section view of a second preferred embodiment of the solar power module having carbon nanotubes in accordance with the present invention is shown.

Similar to the previous first embodiment shown in FIG. 2, the solar power module includes a first conducting layer 5b, an electron donor layer 7, a plurality of carbon nanotubes 9, and a second conducting layer 11b. Contrary to the first embodiment, the second conducting layer 11b of FIG. 3 is transparent to the light and connects the carbon nanotubes 9. For the second conducting layer 11b is transparent and its connection with the carbon nanotubes 9, the excited electrons 6 generated in the electron donor layer 7 are output through the carbon nanotubes 9 and the second conducting layer 11b, while the holes 2 are output through the first conducting layer 5b.

The first conducting layer 5b of the present embodiment is used for outputting the holes 2 and can be used as a substrate to hold the electron donor layer 7.

In this embodiment, the transparent second conducting layer 11b can be made of an indium oxide, a tin oxide, an indium tin oxide (ITO), or any metal oxide the like. Or, the first conducting layer 5a can be an extreme thin metal foil such as a gold foil or a silver foil. Also, the second conducting layer 11b can be partially transparent and can include an anti-reflection coating. The catalyst for growing the carbon nanotubes 9 can be Fe, Co, Ni, Pt, Pd, or Ag. In a particular production, the carbon nanotubes 9 can be printed to the second conducting layer 11b, without the usage of the catalyst. Further, the second conducting layer 11b can be optionally protected by an inert transparent layer such as a glass layer. The nanotube can be directly growthed by thermal CVD or PECVD, etc.

In this embodiment, the electron donor layer 7, sandwiched between the first conducting layer 5b and the second conducting layer 11b, is functioned and formed similarly to that in the first embodiment. Therefore, the description thereupon is omitted therein.

The carbon nanotubes 9 connected to the transparent second conducting layer 11b as the electron acceptors can be doped to present the N-type carbon nanotubes and are submerged in the electron donor layer 7 for forwarding the accepted electrons 6 to the second conducting layer 11b. The outer surface and the inner surface of each carbon nanotube 9 play the heterojunction between the electron donor (the surrounding material 7) and the electron acceptor (the carbon nanotube 9). Such an pairing is similar to a p-n junction seen in the solar cell which has a silicon base chip. In the present invention, for both the outer and the inner surfaces of the carbon nanotube 9 can be used as the heterojunctions, the working area between the electron donors and the electron acceptors can be greatly increased. Thus, the efficiency of the solar power module according to the present invention can be greatly increased.

Further, for the carbon nanotubes 9 are widely extended in the electron donor layer 7 so as to increase the heterojunction, the possibility of recombining the electron and the respective hole (4) has been effectively lowered. Thereby, the efficiency of the solar power module according to the present invention can be substantially increased.

Similarly, the carbon nanotube can be particularly doped to present an N-type carbon nanotube, and can be a single-walled carbon nanotube, a multi-walled carbon nanotube, or a nano carbon fiber structure.

On the other hand, for every carbon nanotube 9 can extend arbitrarily or orderly in the electron donor layer 7, the effective contact area between the carbon nanotube and the surrounding conducting polymer 7 can be substantially increased and thus the optic-electric conversion efficiency can be greatly lifted as well.

In another embodiment (not shown here), an additional substrate can be included to support the first conducting layer 5b of FIG. 3. The substrate can be made of a ductile material, a metal or a silicon.

By providing the solar power module of the second embodiment of the present invention, the light can enter the electron donor layer 7, through the transparent second conducting layer 11b, to excite the electrons, the excited electrons 6 are then forwarded to the second conducting layer 11b through the carbon nanotubes 9.

By providing the present invention, both the inner and the outer surfaces of the arbitrary-extending carbon nanotube are used as the heterojunction so that the contact working area between the electron donor material and the acceptors (the carbon nanotubes) is greatly increased. Further, for the carbon nanotube has an excellent electric and thermal conductivity, the efficiency of the solar power module of the present invention can be remarkably enhanced. Also, for the material cost for the carbon nanotubes and the electro-donor polymer is much lower than that for the conventional silicon, the production cost of the solar power module of the present invention can be greatly reduced.

While the present invention has been particularly shown and described with reference to a preferred embodiment, it will be understood by those skilled in the art that various changes in form and detail may be without departing from the spirit and scope of the present invention.

I claim:

1. A solar power module having carbon nanotubes, comprising:
a first conducting layer, at least partially transparent, for accepting and further outputting holes;
a second conducting layer for accepting and further outputting electrons; and
a mixing layer for donating and forwarding the electrons and the holes, sandwiched between the first conducting layer and the second conducting layer, further comprising:
a polymer for donating the electrons and the holes after receiving a light incoming from the first conducting layer; and
a plurality of carbon nanotubes, connecting to either the first conducting layer or the second conducting layer for forwarding the electrons respectively to either the first conducting layer or the second conducting layer.

2. The solar power module having carbon nanotubes according to claim 1, wherein said carbon nanotubes are N-type carbon nanotubes grown from catalysts on said first conducting layer.

3. The solar power module having carbon nanotubes according to claim 2, wherein said catalysts are selected from the group of Fe, Co, Ni, Pt, Pd, and Ag.

4. The solar power module having carbon nanotubes according to claim 1, wherein said carbon nanotubes are N-type carbon nanotubes grown from catalysts on said second conducting layer.

5. The solar power module having carbon nanotubes according to claim 4, wherein said catalysts are selected from the group of Fe, Co, Ni, Pt, Pd, and Ag.

6. The solar power module having carbon nanotubes according to claim 1, wherein said first conducting layer is made of a material selected from the group of metal foils and metal oxides.

7. The solar power module having carbon nanotubes according to claim 6, wherein said metal oxides are selected from the group of an indium oxide, a tin oxide, and an indium tin oxide (ITO).

8. The solar power module having carbon nanotubes according to claim 6, wherein said metal foils are selected from the group of gold and silver.

9. The solar power module having carbon nanotubes according to claim 1, wherein said polymer is a P-type poly phenylethylene chemical.

10. The solar power module having carbon nanotubes according to claim 9, wherein said P-type poly phenylethylene chemical is selected from the group of a poly-3-hexylthiophene (P3HT) and a perylenetetracarboxylic-bis-benzimidazole (PTCBI).

11. The solar power module having carbon nanotubes according to claim 1, further including a transparent layer to protect said first conducting layer.

12. The solar power module having carbon nanotubes according to claim 11, wherein said transparent layer is a glass layer.

13. The solar power module having carbon nanotubes according to claim 1, further including a substrate to support said second conducting layer.

14. The solar power module having carbon nanotubes according to claim 13, wherein said substrate is made of a material selected from the group of a ductile material, a metal, and a silicon.

15. The solar power module having carbon nanotubes according to claim 1, wherein said carbon nanotubes are one of the group of single-walled carbon nanotubes, multi-walled carbon nanotubes, and nano carbon fiber structures.

16. The solar power module having carbon nanotubes according to claim 1, wherein said carbon nanotubes are N-type carbon nanotubes.
